(19) United States
(12) Patent Application Publication
(10) Pub. No.: US 2023/0212782 A1
(43) Pub. Date: Jul. 6, 2023

(54) METHOD FOR MANUFACTURING SILICON SINGLE-CRYSTAL SUBSTRATE AND SILICON SINGLE-CRYSTAL SUBSTRATE

(71) Applicant: SHIN-ETSU HANDOTAI CO., LTD., Tokyo (JP)

(72) Inventors: Weifeng QU, Takasaki-shi (JP); Shizuo IGAWA, Annaka-shi (JP); Ken SUNAKAWA, Annaka-shi (JP)

(73) Assignee: SHIN-ETSU HANDOTAI CO., LTD., Tokyo (JP)

(21) Appl. No.: 18/019,916

(22) PCT Filed: Jul. 23, 2021
(86) PCT No.: PCT/JP2021/027435

§ 371 Date: Feb. 6, 2023

(30) Foreign Application Priority Data
Aug. 26, 2020 (JP) 2020-142956

(51) Int. Cl. C30B 29/06; C30B 31/06; C30B 33/12; C30B 33/02

(52) U.S. Cl. CPC C30B 29/06; C30B 31/06; C30B 33/12; C30B 33/02

(57) ABSTRACT

A method for manufacturing a silicon single-crystal substrate having a carbon diffusion layer on a surface, proximity gettering ability, and high strength near the surface, and hardly generating dislocation or extending dislocation, includes: a step of adhering carbon on a surface of a silicon single-crystal substrate by an RTA treatment of the silicon single-crystal substrate in a carbon-containing gas atmosphere; a step of forming a 3C-SiC single-crystal film on the surface of the silicon single-crystal substrate by reacting the carbon and the silicon single-crystal substrate; a step of oxidizing the 3C-SiC single-crystal film to be an oxide film and diffusing carbon inward the silicon single-crystal substrate by an RTA treatment of the silicon single-crystal substrate on which the 3C-SiC single-crystal film is formed, the RTA treatment being performed in an oxidative atmosphere; and a step of removing the oxide film.

### TECHNICAL FIELD

The present invention relates to a silicon single-crystal substrate having a carbon diffusion layer on a surface, and a manufacturing method thereof.

### BACKGROUND ART

To impart proximity gettering ability to a surface layer of a silicon single-crystal substrate or to inhibit slip dislocation, it has been proposed to inject nitrogen or carbon into the surface layer of the silicon single-crystal substrate by a heat treatment.

For example, Patent Document 1 discloses that an RTA treatment in a nitrogen-containing gas atmosphere inhibits the slip dislocation. Patent Document 2 discloses a heat treatment in an atmosphere containing a carbon-containing gas so that a carbon concentration is saturated at any position within a distance of 5 μm from a surface into the depth direction. In this case, the saturated carbon concentration is a solid solubility of carbon at a highest temperature during the heat treatment. For example, a saturated concentration of carbon is disclosed to be 11×10¹⁶ atoms/cm³ when a silicon wafer is heated at 1200° C. Patent Document 3 discloses a method for manufacturing an epitaxial silicon wafer in which a carbon diffusion layer is formed on a surface layer by a heat treatment in a carbon-containing gas atmosphere, and then an epitaxial layer is formed thereon.

### CITATION LIST

### Patent Literature

Patent Document 1: JP 2002-110685 A

Patent Document 2: JP 2018-190903 A

Patent Document 3: JP 2020-43232 A

Patent Document 4: JP 2016-111044 A

### SUMMARY OF INVENTION

### Technical Problem

The present inventors have earnestly made investigation, and found a problem that the nitrogen-doped silicon single-crystal substrate, as described in Patent Document 1, has a large diffusion coefficient of nitrogen, and thereby outward diffusion rate is high and fails to sufficiently increase a nitrogen concentration in a surface layer. In contrast, carbon has a small diffusion coefficient and a carbon concentration in the surface layer can be increased.

However, such a method described in Patent Document 2 is insufficient. To inhibit the slip dislocation more certainly, required is forming a carbon diffusion layer having a concentration higher than the saturated concentration. Although a peak concentration in the carbon diffusion layer described in Patent Document 3 is as high as 1×10¹⁸ to 1×10²⁰ atoms/cm³, the carbon diffusion layer has a thickness of 200 nm or less, and such a thin layer is insufficient for more certainly inhibit the slip dislocation.

The present invention has been made to solve above-described problem. An object of the present invention is to provide: a silicon single-crystal substrate that has proximity gettering ability, that has high strength near the surface, and that hardly generates dislocation or extends dislocation; and a manufacturing method thereof.

### Solution to Problem

The present invention has been made to achieve the above object. The present invention provides a method for manufacturing a silicon single-crystal substrate having a carbon diffusion layer on a surface, the method comprising: a step of adhering carbon on a surface of a silicon single-crystal substrate by an RTA treatment of the silicon single-crystal substrate in a carbon-containing gas atmosphere; a step of forming a 3C-SiC single-crystal film on the surface of the silicon single-crystal substrate by reacting the carbon and the silicon single-crystal substrate; a step of oxidizing the 3C-SiC single-crystal film to be an oxide film and diffusing carbon inward the silicon single-crystal substrate by an RTA treatment of the silicon single-crystal substrate on which the 3C-SiC single-crystal film is formed, the RTA treatment being performed in an oxidative atmosphere; and a step of removing the oxide film.

Such a method for manufacturing a silicon single-crystal substrate can manufacture a silicon single-crystal substrate having proximity gettering ability, high strength near the surface, and hardly generating dislocation or extending dislocation.

In this time, the method for manufacturing a silicon single-crystal substrate can be a method, wherein in the step of adhering carbon on the surface of the silicon single-crystal substrate, a temperature of the RTA treatment is lower than 800° C.

Such a method enables a sufficient amount of carbon to more stably adhere on the surface of the silicon single-crystal substrate in a short time.

In this time, the method for manufacturing a silicon single-crystal substrate can be a method, wherein in the step of forming the 3C-SiC single-crystal film on the surface of the silicon single-crystal substrate, the 3C-SiC single-crystal film having a thickness of 7 nm or less is formed on the surface of the silicon single-crystal substrate by an RTA treatment in a carbon-containing gas atmosphere at 1150° C. to 1300° C.

This method can efficiently and stably form a 3C-SiC single-crystal film.

In this time, the method for manufacturing a silicon single-crystal substrate can be a method, wherein in the step of oxidizing the 3C-SiC single-crystal film to be the oxide film and diffusing carbon inward the silicon single-crystal substrate, the RTA treatment is performed in the oxygen atmosphere at 1150° C. to 1400° C. for 1 to 60 seconds.

This method can stably form a carbon diffusion layer having a carbon concentration of 1×10¹⁷ atoms/cm³ or more and thickness of 2 μm or more on the surface of the silicon single-crystal substrate.

In this time, the method for manufacturing a silicon single-crystal substrate can be a method, wherein in the step of removing the oxide film, the oxide film is etched by an RTA treatment in a hydrogen atmosphere at 1150° C. to 1400° C. for 1 to 60 seconds.

Since this method can be performed with the same apparatus followed by the RTA treatment from the previous step, the treatment can be easily performed with high productivity.

In this time, the method for manufacturing a silicon single-crystal substrate can be a method, wherein in the step of removing the oxide film, etching is performed with 0.1 to 5.0% hydrofluoric acid (an aqueous HF solution) for shorter than 10 minutes, and then rinsing is performed with pure water.

This method can simply remove the oxide film, and whether the oxide film is removed or not is easily judged.

In this time, the method for manufacturing a silicon single-crystal substrate can be a method, wherein the step of oxidizing the 3C-SiC single-crystal film to be the oxide film and diffusing carbon inward the silicon single-crystal substrate and the step of removing the oxide film are repeated.

This method can certainly remove the 3C-SiC single-crystal film.

In this time, a method for manufacturing a silicon epitaxial wafer can be a method comprising forming an epitaxial layer on a silicon single-crystal substrate manufactured by the method for manufacturing a silicon single-crystal substrate.

This method can manufacture a silicon epitaxial wafer having proximity gettering ability, having high strength near the surface, and hardly generating dislocation or extending dislocation.

The present invention can also provide a silicon single-crystal substrate comprising a carbon diffusion layer on a surface, wherein the carbon diffusion layer has a carbon concentration of 1×10¹⁷ atoms/cm³ or more and a thickness of 2 μm or more.

Such a silicon single-crystal substrate has proximity gettering ability, has high strength near the surface, and hardly generates dislocation or extends dislocation.

In this time, a silicon epitaxial wafer can be a wafer comprising an epitaxial layer on the carbon diffusion layer in the silicon single-crystal substrate.

Such a silicon epitaxial wafer has proximity gettering ability, has high strength near the surface, and hardly generates dislocation or extends dislocation.

### Advantageous Effects of Invention

As described above, the inventive method for manufacturing a silicon single-crystal substrate can provide a silicon single-crystal substrate having proximity gettering ability, having high strength near the surface, and hardly generating dislocation or extending dislocation. The inventive silicon single-crystal substrate has proximity gettering ability, has high strength near the surface, and hardly generates dislocation or extends dislocation.

### BRIEF DESCRIPTION OF DRAWINGS

FIG. 1 illustrates an outline of a manufacturing process of a silicon single-crystal substrate having a carbon diffusion layer.

FIG. 2 indicates comparison of a carbon concentration in a silicon single-crystal substrate.

FIG. 3 is a graph indicating comparison of carbon concentrations before and after an RTA treatment in an oxygen atmosphere.

FIG. 4 is a view illustrating behavior of smoothing distribution of a carbon concentration by repeated RTA in an oxygen atmosphere.

FIG. 5 shows evaluation results (SIMS, rosette test) of silicon single-crystal substrates according to Example 1 and Comparative Example 1.

FIG. 6 shows results of SEM observation of a silicon single-crystal substrate according to Example 2.

FIG. 7 shows results of SIMS measurement of a silicon single-crystal substrate according to Example 2 (heat-treatment temperature: 1150° C.)

FIG. 8 shows results of SIMS measurement of a silicon single-crystal substrate according to Example 2 (heat-treatment temperature: 1175° C.)

FIG. 9 shows results of SIMS measurement of a silicon single-crystal substrate according to Example 2 (heat-treatment temperature: 1200° C.)

FIG. 10 shows results of SIMS measurement of a silicon epitaxial wafer according to Example 3.

FIG. 11 shows results of SEM observation of a silicon epitaxial wafer according to Example 3.

### DESCRIPTION OF EMBODIMENTS

Hereinafter, the present invention will be described in detail, but the present invention is not limited thereto.

As described above, there have been demands for a silicon single-crystal substrate having proximity gettering ability, having high strength near the surface, and hardly generating dislocation or extending dislocation. The present inventors have found that the above problem can be solved by forming, as a surface layer of a silicon single-crystal substrate, a carbon diffusion layer as thick as 2 μm or more having a carbon concentration equal to or higher than the solid solubility. In addition, the present inventors have found that the carbon diffusion layer having a high carbon concentration and being as thick as 2 μm or more can be formed by forming a 3C-SiC single-crystal film on the surface of the silicon single-crystal substrate and then performing an oxidation treatment to convert the 3C-SiC single-crystal film into an oxide film and to allow the carbon to be diffused toward the surface layer of the silicon substrate. This finding has led to the completion of the present invention.

The present inventors have earnestly studied the above problem and consequently found that the silicon single-crystal substrate having proximity gettering ability, having high strength near the surface, and hardly generating dislocation or extending dislocation can be manufactured by a method for manufacturing a silicon single-crystal substrate having a carbon diffusion layer on a surface, the method comprising: a step of adhering carbon on a surface of a silicon single-crystal substrate by an RTA treatment of the silicon single-crystal substrate in a carbon-containing gas atmosphere; a step of forming a 3C-SiC single-crystal film on the surface of the silicon single-crystal substrate by reacting the carbon and the silicon single-crystal substrate; a step of oxidizing the 3C-SiC single-crystal film to be an oxide film and diffusing carbon inward the silicon single-crystal substrate by an RTA treatment of the silicon single-crystal substrate on which the 3C-SiC single-crystal film is formed, the RTA treatment being performed in an oxidative atmosphere; and a step of removing the oxide film. This finding has led to the completion of the present invention.

The present inventors have also found that a silicon single-crystal substrate, comprising a carbon diffusion layer on a surface, wherein the carbon diffusion layer has a carbon concentration of 1×10¹⁷ atoms/cm³ or more and a thickness of 2 μm or more is the silicon single-crystal substrate having proximity gettering ability, having high strength near the surface, and hardly generating dislocation or extending dislocation. This finding has led to the completion of the present invention.

Hereinafter, the description will be made with reference to the drawings.

(Silicon Single-Crystal Substrate Comprising Carbon Diffusion Layer)

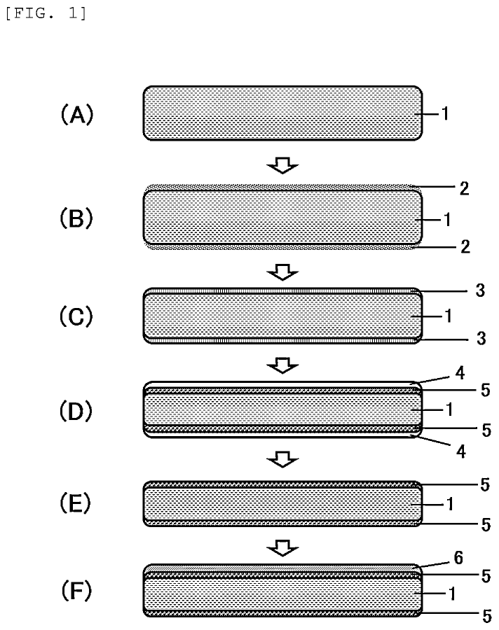

First, the inventive silicon single-crystal substrate comprising the carbon diffusion layer will be described. FIG. 1 is a view illustrating an outline of a manufacturing process of the inventive silicon single-crystal substrate having the carbon diffusion layer, described later. FIG. 1(E) illustrates the inventive silicon single-crystal substrate. As illustrated in FIG. 1(E), the inventive silicon single-crystal substrate comprises a carbon diffusion layer 5 on a surface of a silicon single-crystal substrate 1, and the carbon diffusion layer 5 has a carbon concentration of 1×10¹⁷ atoms/cm³ or more and a thickness of 2 μm or more. The silicon single-crystal substrate having such a carbon diffusion layer 5 has proximity gettering ability, has high strength near the surface, and hardly generates dislocation or extends dislocation.

An upper limit of the carbon concentration in the carbon diffusion layer 5 and a thickness of the carbon diffusion layer 5 can be appropriately regulated with RTA-treatment conditions and a number of times of the RTA treatment, as described later, and not particularly limited. The carbon concentration may be, for example, 1×10¹⁹ atoms/cm³ or less. The thickness may be, for example, 5 μm or less.

As the silicon single-crystal substrate, any silicon single-crystal substrate can be used regardless of a defective region of crystals, a diameter, conductivity (type and resistivity), etc. For example, a silicon single-crystal substrate obtained by slicing a silicon single-crystal ingot grown by a Czochralski method can be used. When the silicon single-crystal substrate is used as a substrate in which a semiconductor device is formed on the surface, a silicon single-crystal substrate without a defective region is preferable not to deteriorate device characteristics. When used as a substrate in which an epitaxial layer is formed on the surface, the silicon single-crystal substrate may be, in particular, any silicon single-crystal substrate. Of course, a silicon single-crystal substrate without a defective region can also be used.

(Silicon Epitaxial Wafer)

As illustrated in FIG. 1(F), an epitaxial layer 6 is preferably comprised on the carbon diffusion layer 5 of the silicon single-crystal substrate to be a silicon epitaxial wafer. Such a silicon epitaxial wafer, which has the epitaxial layer without defect on the surface and has proximity gettering function directly thereunder, hardly generates dislocation.

(Method for Manufacturing Silicon Single-Crystal Substrate Comprising Carbon Diffusion Layer)

Next, a method for manufacturing the inventive silicon single-crystal substrate having the carbon diffusion layer will be described. FIG. 1 illustrates an outline of a manufacturing process of the inventive silicon single-crystal substrate having the carbon diffusion layer.

<Step of Preparing Silicon Single-Crystal Substrate>

First, a silicon single-crystal substrate 1 is prepared (FIG. 1(A)). As described above, the inventive silicon single-crystal substrate 1 may be any silicon single-crystal substrate.

<Step of Adhering Carbon on Surface of Silicon Single-Crystal Substrate>

Then, to adhere carbon 2 on a surface of the silicon single-crystal substrate 1, an RTA treatment is performed in a carbon-containing gas atmosphere (FIG. 1(B)). This treatment enables to form a 3C-SiC single-crystal film in the following step. The carbon-containing gas atmosphere in this step may be, for example, a mixed atmosphere of: any of CH₄, C₂H₄, and C₃H₈ gasses; and Ar+H₂. A carbon concentration in this time is desirably 0.5% or more and less than 10%. The RTA condition is not particularly limited as long as the condition can adhere the carbon 2 on the surface of the silicon single-crystal substrate 1, and may be a low temperature condition, for example, 600° C. or higher and lower than 800° C. for 1 to 60 seconds.

A heat-treatment temperature with a common RTA apparatuses is 600° C. or higher. The heat-treatment temperature of 600° C. or higher can certainly achieve adhesion to bond the carbon onto silicon on the substrate surface. In this time, if the heat-treatment temperature is 800° C. or higher, silicon starts to be volatilized from the substrate surface to loss the bonded carbon and silicon from the substrate surface, which may destabilize the carbon adhesion. Thus, to stably adhere the carbon, the heat-treatment temperature is preferably lower than 800° C. This RTA treatment enables to adhere the carbon on the surface of the silicon single-crystal substrate.

<Step of Forming 3C-SiC Single-Crystal Film on Surface of Silicon Single-Crystal Substrate>

Then, the carbon 2 and silicon of the silicon single-crystal substrate 1 are reacted to form a 3C-SiC single-crystal film 3 on the surface of the silicon single-crystal substrate 1 (FIG. 1(C)). In this time, silicon on the surface of the silicon single-crystal substrate 1 and the carbon 2 adhered onto the surface of the silicon single-crystal substrate 1 are reacted to form a single crystal, and this single crystal becomes a seed crystal to form a thin 3C-SiC single-crystal film 3 on the surface of the silicon single-crystal substrate 1. The treatment condition in this time is not particularly limited as long as the carbon and the silicon are reacted to form the 3C-SiC single-crystal film. For example, an RTA treatment can be performed in a carbon-containing gas atmosphere at a temperature higher than the that in adhering carbon. Since the RTA treatment can be performed with the same apparatus followed by the previous step of adhering carbon, such a treatment is effective, and has no risk of contamination, etc. involved with transfer between apparatuses like using another apparatus. The carbon-containing gas atmosphere in this time is preferably same as in the step of adhering the carbon on the surface of the silicon single-crystal substrate. A specific RTA condition can be 1150° C. to 1300° C. for 1 to 60 seconds. This RTA treatment stably forms the 3C-SiC single-crystal film 3 with 7 nm or less on the surface of the silicon single-crystal substrate. When the 3C-SiC film 3 is formed on the surface of the silicon single-crystal substrate 1, carbonization of silicon on the surface of the silicon single-crystal substrate 1 does not proceed furthermore, and the thickness of the 3C-SiC single-crystal film 3 has an upper limit of 7 nm.

<Step of Oxidizing 3C-SiC Single-Crystal Film and Inward Diffusing Carbon>

Then, the silicon single-crystal substrate 1 on which the 3C-SiC single-crystal film 3 is formed is RTA-treated in an oxidative atmosphere to oxidize the 3C-SiC single-crystal film 3 and form an oxide film 4, and to diffuse carbon inward the silicon single-crystal substrate 1 (FIG. 1(D)). Converting the 3C-SiC single-crystal film 3 into the oxide film 4 in this step facilitates removal of the oxide film 4, formed by converting the 3C-SiC single-crystal film 3, in the following step. In addition, the inward diffusing carbon in the 3C-SiC single-crystal film 3 from the surface of the silicon single-crystal substrate 1 forms the carbon diffusion layer 5 having a carbon concentration of 1×10¹⁷ atoms/cm³ or more and a thickness of 2 μm or more on the surface of the silicon single-crystal substrate 1. In this time, the silicon single-crystal substrate preferably has a peak value of the carbon concentration of 1×10¹⁸ atoms/cm³ or more at any position within a range of 2 μm from the surface.

The RTA condition in this step may be, for example, an oxygen atmosphere at 1150° C. to 1400° C. for 1 to 60 seconds. Under such a condition, the carbon diffusion layer 5 having a carbon concentration of 1×10¹⁷ atoms/cm³ or more and a thickness of 2 μm or more can be stably formed on the surface of the silicon single-crystal substrate 1.

In this time, a thickness of the 3C-SiC single-crystal film that can be converted into the oxide film with one RTA treatment is limited. Thus, when one RTA treatment fails to complete the oxidization and the 3C-SiC single-crystal film 3 is remained, this RTA treatment in the oxidative atmosphere may be repeated.

In this 3C-SiC single-crystal film 3, carbon is present at a density on the order of 10²² atoms/cm³. By the RTA treatment in the oxidative atmosphere, the carbon in the 3C-SiC single-crystal film 3 is diffused inward the silicon single-crystal substrate 1. This diffusion continues until the 3C-SiC single-crystal film 3 is entirely converted into the oxide film 4, and thereby the carbon diffusion layer 5 having a peak concentration of 1×10¹⁸ atoms/cm³ or more, much higher than 3×10¹⁶ atoms/cm³ being the solid solubility of carbon at 1200° C., can be formed on the surface, for example. In this time, when the RTA treatment is continuously performed even after the 3C-SiC single-crystal film 3 is entirely converted into the oxide film, diffusion continues without the carbon diffusion from the 3C-SiC single-crystal film. Thus, the peak value of the carbon concentration shifts inward the substrate, and the distribution of the carbon concentration in the depth direction becomes smooth.

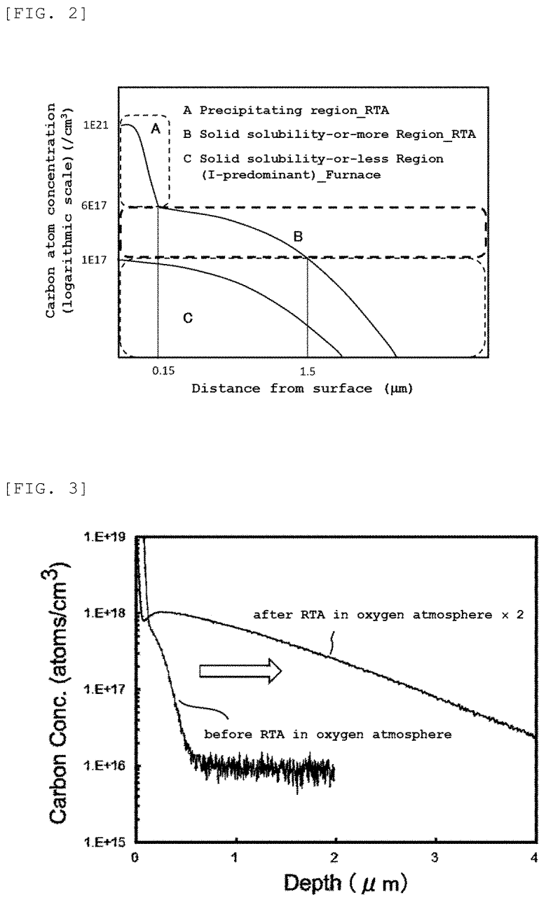

FIG. 2 indicates comparison of the carbon concentration in the silicon single-crystal substrate. When the 3C-SiC single-crystal film is formed on the silicon substrate, the concentration on a boundary of 3C-SiC/Si is approximately 10²² atoms/cm³, and the carbon is diffused inward the silicon substrate side by the concentration gradient during the RTA treatment step. In this time, in an area where the concentration is higher than the solid solubility, the carbon clusters to precipitate as an area A in FIG. 2. Inside the silicon single-crystal substrate, as an area B in FIG. 2, the carbon diffusion layer having a carbon concentration exceeding the solid solubility of carbon is formed. Since the carbon is supplied by the inward diffusion, the carbon concentration is lower with a longer distance from the substrate surface. Meanwhile, an area C in FIG. 2, which indicates a case where the carbon diffusion layer is formed by the heat treatment in the carbon-containing gas atmosphere as described in Patent Document 2, shows that the carbon concentration in the carbon diffusion layer cannot be equal to or higher than the solid solubility.

As described above, the inward diffusing carbon from the 3C-SiC single-crystal film into the silicon single-crystal substrate 1 allows the carbon concentration of the carbon diffusion layer 5 to be higher than the solid solubility, and the thick carbon diffusion layer 5 at the high concentration can be formed.

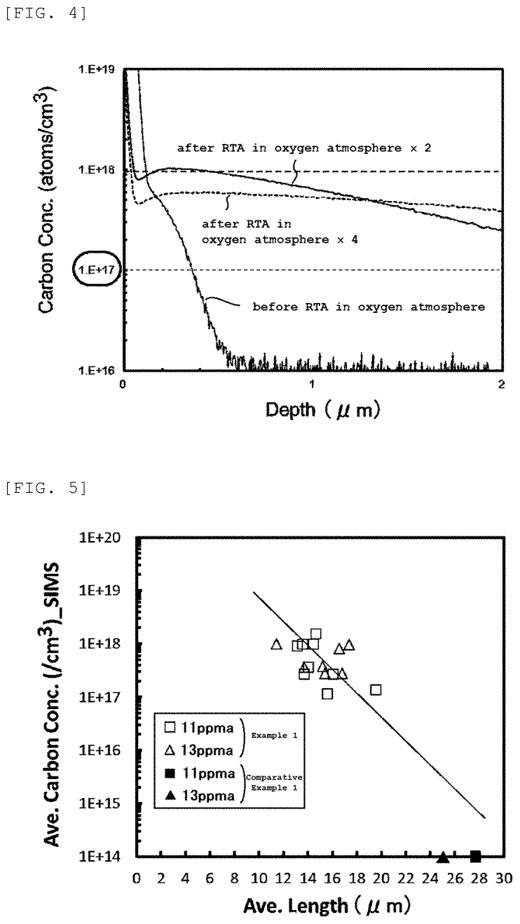

In this time, when the silicon single-crystal substrate comprising the carbon diffusion layer is used as a substrate of the silicon epitaxial wafer, the peak value of the carbon concentration is preferably closer to the substrate surface. When the silicon single-crystal substrate comprising the carbon diffusion layer is used as a silicon single-crystal substrate for a device formation, a DZ layer without defect is preferably formed on the surface, and the peak value of the carbon concentration is preferably present immediately thereunder. Since the position of the peak value of the carbon concentration to be formed is determined by the RTA condition, an optimal RTA condition can be determined depending on usage of the silicon single-crystal substrate. FIG. 3 is a graph indicating comparison of the carbon concentrations near the surface before and after the RTA treatment in the oxidative atmosphere, and shows behavior that the carbon at a high concentration is diffused by the RTA treatment in the oxidative atmosphere. FIG. 4 is a view illustrating behavior of smoothing distribution of the carbon concentration by the repeated RTA in an oxygen atmosphere to further inward diffuse the carbon.

<Step of Removing Oxide Film>

Then, the oxide film 4 is removed (FIG. 1(E)). A treatment method for removing the oxide film 4 is not particularly limited, and the oxide film 4 can be removed by a method as below.

A first method for removing the oxide film is a method of etch-removing the oxide film by an RTA treatment in a hydrogen (H₂) atmosphere. Specifically, the RTA condition may be a H₂ atmosphere at 1150° C. to 1400° C. for 1 to 60 seconds. Such a method for removing the oxide film by the RTA treatment is more convenient because the oxide film removing treatment can be subsequently performed using the RTA apparatus used for the step of oxidizing the 3C-SiC single-crystal film and diffusing carbon. Note that, by this method, whether the oxide film is completely removed cannot be determined by visually observing the silicon single-crystal substrate after taking out from the RTA treatment apparatus. Thus, etching with hydrofluoric acid (aqueous HF solution) is preferably performed thereafter.

In this RTA treatment, the carbon in the carbon diffusion layer formed on the surface is also diffused again. Thus, the condition of the above RTA treatment in the oxygen atmosphere and the condition of the subsequent RTA treatment in the hydrogen atmosphere are preferably determined so that the carbon diffusion layer is formed at a target depth. When the 3C-SiC single-crystal film is incompletely converted into the oxide film and is still present, the carbon diffusion from the 3C-SiC single-crystal film continues even in this step of etch-removing the oxide film.

As a second method for removing the oxide film instead of the RTA treatment in the hydrogen atmosphere, the oxide film can also be removed by a wet treatment using hydrofluoric acid (aqueous HF solution). For example, etching can be performed with 0.1 to 5.0% hydrofluoric acid (aqueous HF solution) for shorter than 10 minutes, and then rinsing is performed with pure water. This method does not diffuse the carbon in the carbon diffusion layer again, and the silicon single-crystal substrate having a hydrophobic surface can be easily checked. Thus, the method is suitable as a method for checking no residue of the 3C-SiC single-crystal film and complete removal of the oxide film.

As described above, the first method for removing the oxide film (RTA treatment in the hydrogen atmosphere) and the second method for removing the oxide film (wet treatment with hydrofluoric acid) can be combined. For example, the RTA treatment in the hydrogen atmosphere is performed, the silicon single-crystal substrate is taken out from the RTA treatment apparatus, and then etching using hydrofluoric acid (aqueous HF solution) is performed. Such a method is effective for visually checking complete removal of the oxide film.

In the step of oxidizing the 3C-SiC single-crystal film and diffusing the carbon, when the 3C-SiC single-crystal film is not entirely converted into the oxide film and the 3C-SiC single-crystal film is remained, preferably performed steps are: removing only the converted oxide film; then converting the remained 3C-SiC single-crystal film into the oxide film again; and then removing the oxide film. In this case, the peak value and peak position of the carbon concentration of the carbon diffusion layer are also changed by repeating the step of oxidizing the 3C-SiC single-crystal film and diffusing the carbon. Thus, the RTA condition is preferably determined with considering these effects.

As described above, entirely converting the 3C-SiC single-crystal film formed on the substrate surface into the oxide film and removing this oxide film can form the thick carbon diffusion layer having a carbon concentration higher than the solid solubility on the substrate surface. This method can yield the silicon single-crystal substrate having a DZ layer without defect on the surface, having the proximity gettering function directly thereunder, hardly generating dislocation, and having high substrate strength.

Polishing both the surface (DSP) of the silicon single-crystal substrate in which the oxide film is removed is preferable because such polishing can yield a smoother surface.

<Step of Forming Epitaxial Layer>

On the silicon single-crystal substrate 1 having the carbon diffusion layer 5 on the surface, obtained as above, an epitaxial layer 6 having desired conductive type, resistivity, and thickness can be formed (FIG. 1(F)). This epitaxial layer 6 can yield a silicon epitaxial wafer having the thick carbon diffusion layer 5 having a carbon concentration higher than the solid solubility near a boundary between the silicon single-crystal substrate 1 and the epitaxial layer 6. Such a step can yield a silicon epitaxial wafer having the epitaxial layer without defect on the surface, having the proximity gettering function directly thereunder, and hardly generating dislocation.

### EXAMPLES

Hereinafter, the present invention will be specifically described with Examples, but the present invention is not limited thereto.

### Example 1

Following silicon single-crystal substrates were prepared.

Diameter: 200 mm, (100), P-type, Resistivity: 14 to 25 Ω·cm

Oxygen concentration: 11, 13 ppma (JEITA)

Crystalline region: NPC region (region without defect)

Then, an RTA treatment was performed to adhere carbon to the surface of the silicon single-crystal substrate. A condition of the RTA treatment was: CH₄/Ar+H₂ (carbon concentration 1.4%) atmosphere; heating from a room temperature to 800° C.; and holding at 800° C. for 20 sec.

Then, an RTA treatment was performed to react the carbon adhered to the surface of the silicon single-crystal substrate with silicon of the silicon single-crystal substrate to be converted into a 3C-SiC single-crystal film. A condition of the RTA treatment was a CH₄/Ar+H₂ (carbon concentration 1.4%) atmosphere at 1200° C. for 10 sec. The 3C-SiC single-crystal film with 2 nm was formed on the surface by this treatment.

Then, an RTA treatment was performed to oxide the 3C-SiC single-crystal film and to diffuse the carbon. A condition of the RTA treatment was an O₂ atmosphere at 1250° C. for 30 sec.

Then, an RTA treatment and a wet etching were performed to remove the oxide film. A condition of the RTA treatment was a H₂ atmosphere at 1250° C. for 30 sec. After the RTA treatment, etching with 2% hydrofluoric acid (HF/H₂O) was performed for 5 minutes. As a result, the substrate surface being a hydrophilic surface was observed, and a remained 3C-SiC single-crystal film was observed.

Accordingly, a second treatment of oxidizing the 3C-SiC single-crystal film and diffusing the carbon was performed. A condition of the RTA treatment was an O₂ atmosphere at 1250° C. for 30 sec.

Then, a second treatment of removing the oxide film was performed. Etching with 2% hydrofluoric acid (HF/H₂O) was performed for 5 minutes to observe the wafer surface having a hydrophobic surface, and consequently observed that the 3C-SiC single-crystal film and the oxide film on the surface were removed.

The silicon single-crystal substrate having the carbon diffusion layer on the surface, obtained as above, was evaluated by a rosette test. The rosette test is an evaluation method described in Patent Document 4. In this evaluation method, a dent is formed on a substrate surface, which is an evaluation object, to apply strain on a surface layer of the substrate. A heat treatment is performed thereafter, and dislocation is extended to measure a length of the dislocation (rosette length). In the evaluation method, a shorter length of the dislocation can be judged to have higher ability to inhibit generation and extension of dislocation.

A condition of the rosette test in the present Example is as follows: a dent depth was 1 μm; and after the denting, a heat treatment was performed in an Ar atmosphere at 900° C./1 hr to measure a dislocation length. A carbon concentration at a distance with 1 μm from the surface was measured by SIMS to determine a relationship between the carbon concentration and the dislocation length. As a result, it is observed that, as shown FIG. 5, the higher the carbon concentration, the shorter the dislocation length, regardless of an oxygen concentration. In FIG. 5, the carbon concentration on the vertical axis indicates an average value up to 1 μm excluding an extremely high value of the surface.

### Comparative Example 1

A rosette test same as Example 1 was performed by using a carbon-doped silicon single-crystal substrate having a carbon doping amount of 1×10¹⁴ atoms/cm³. A substrate in Comparative Example 1 results an extremely long dislocation length, shown as “▪” and “▴” in FIG. 5. That is, it is found that the silicon single-crystal substrate having the carbon diffusion layer on the surface in Example 1, which has a high carbon concentration near the surface, has extremely higher ability to inhibit generation and extension of dislocation than the carbon-doped silicon single-crystal substrate in Comparative Example 1, which has a carbon concentration of 1×10¹⁴ atoms/cm³.

### Example 2

Next, confirmed was a gettering ability of the surface layer of the inventive silicon single-crystal substrate having the carbon diffusion layer on the surface. A used silicon single-crystal substrate was as follows.

Diameter: 200 mm, (100), P-type, Resistivity: 14 to 25 Ω·cm

Oxygen concentration: 13 ppma (JEITA)

Crystalline region: NPC region (region without defect)

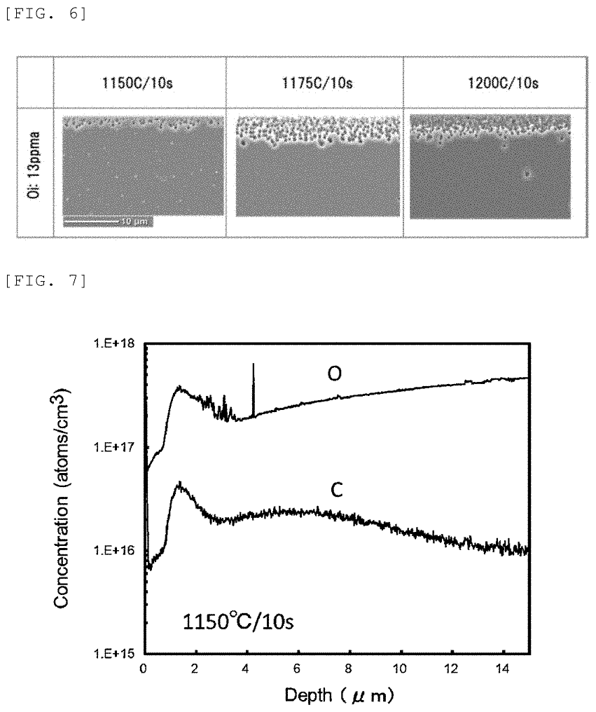

Silicon single-crystal substrates having the carbon diffusion layer on the surface were obtained under a condition similar to in Example 1 except that the heat treatment temperature in the RTA treatment in the oxygen atmosphere was 1150° C., 1175° C., or 1200° C. for 10 sec. These substrate were subjected to an oxygen-precipitation heat treatment (650° C./4 hr in N₂+800° C./4 hr in N₂+1000° C./16 hr in O₂) to evaluate the oxygen precipitation. A cross section was exposed by reactive-ion etching to perform SEM observation (hereinafter, referred to as “RIE+SEM”). FIG. 6 show the evaluation results. From this evaluation, it was confirmed that an oxygen-precipitation layer was formed near the surface of the silicon single-crystal substrate.

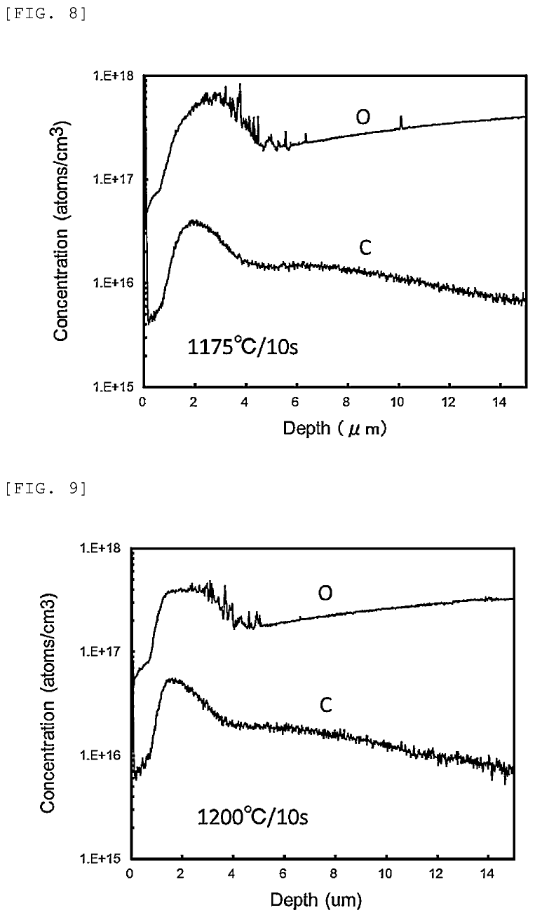

FIGS. 7 to 9 show the SIMS measurement results of the silicon single-crystal substrates according to Example 2 (heat treatment temperature: 1150° C., 1175° C., or 1200° C.). From the evaluation by the SIMS measurement shown in FIGS. 7 to 9, it was found that a DZ layer with approximately 1 μm was formed on a surface layer of the silicon single-crystal substrate. In addition, it was confirmed that peak values of carbon and oxygen were present in the oxygen precipitation region.

### Example 3

An epitaxial layer was formed on the silicon single-crystal substrate having the carbon diffusion layer on the surface, obtained in Example 1. A used silicon single-crystal substrate was as follows.

Diameter: 200 mm, (100), P-type, Resistivity: 14 to 25 Ω·cm

Oxygen concentration: 11 ppma (JEITA)

Crystalline region: NPC region (region without defect)

A carbon diffusion layer was formed on the surface under a condition same as in Example 1 except that the RTA treatment for conversion into the 3C-SiC single-crystal film was performed at 1175° C./10 sec, 1.4% CH₄/Ar+H₂. Then, a Si-epitaxial film was grown at a film-forming temperature of 1130° C. for a thickness target of 4 μm. Thereafter, an oxygen-precipitation heat treatment was performed at 650° C./4 hr in N₂+800° C./4 hr in N₂+1000° C./4 hr in O₂.

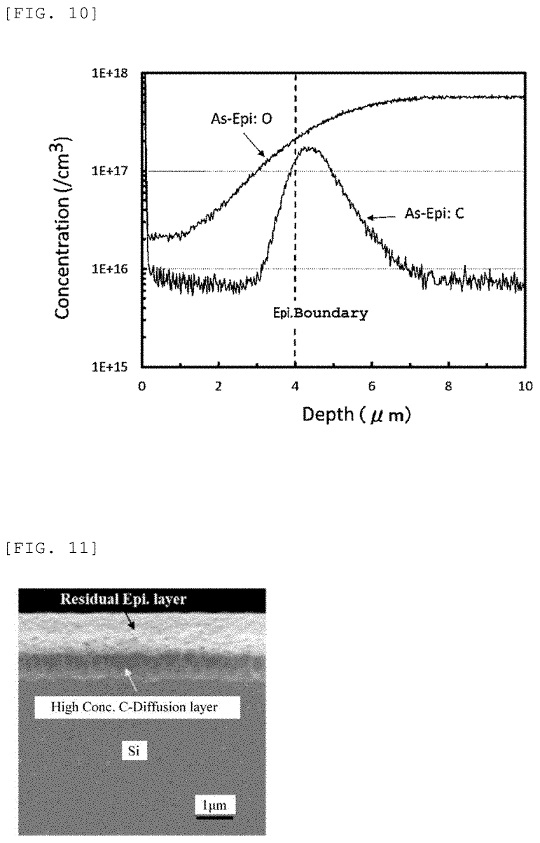

Changes in carbon and oxygen concentrations near the wafer surface after the oxygen-precipitation heat-treatment process were evaluated by SIMS. In addition, the oxygen precipitation after the oxygen-precipitation heat-treatment process were evaluated by RIE+SEM. As a result, from evaluation by the SIMS measurement shown in FIG. 10, it was confirmed that the carbon diffusion region having a thickness of approximately 2 μm and a carbon concentration of more than 1×10¹⁷ atoms/cm³ was formed near the boundary between the silicon single-crystal substrate and the epitaxial layer. As shown in the RIE+SEM observation result in FIG. 11, it was confirmed that the oxygen precipitation layer was formed in the carbon diffusion region.

As described above, it has been found that the inventive Example can yield the silicon single-crystal substrate and silicon epitaxial wafer that has extremely high ability to inhibit generation and extension of dislocation, that can form the oxygen precipitation layer near the surface of the silicon single-crystal substrate, and that has the carbon diffusion layer on the surface.

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1-10. (canceled)

11. A method for manufacturing a silicon single-crystal substrate having a carbon diffusion layer on a surface, the method comprising:
a step of adhering carbon on a surface of a silicon single-crystal substrate by an RTA treatment of the silicon single-crystal substrate in a carbon-containing gas atmosphere;
a step of forming a 3C-SiC single-crystal film on the surface of the silicon single-crystal substrate by reacting the carbon and the silicon single-crystal substrate;
a step of oxidizing the 3C-SiC single-crystal film to be an oxide film and diffusing carbon inward the silicon single-crystal substrate by an RTA treatment of the silicon single-crystal substrate on which the 3C-SiC single-crystal film is formed, the RTA treatment being performed in an oxidative atmosphere; and
a step of removing the oxide film.

12. The method for manufacturing a silicon single-crystal substrate according to claim 11, wherein in the step of adhering carbon on the surface of the silicon single-crystal substrate, a temperature of the RTA treatment is lower than 800° C.

13. The method for manufacturing a silicon single-crystal substrate according to claim 11, wherein in the step of forming the 3C-SiC single-crystal film on the surface of the silicon single-crystal substrate, the 3C-SiC single-crystal film having a thickness of 7 nm or less is formed on the surface of the silicon single-crystal substrate by an RTA-treatment in a carbon-containing gas atmosphere at 1150° C. to 1300° C.

14. The method for manufacturing a silicon single-crystal substrate according to claim 12, wherein in the step of forming the 3C-SiC single-crystal film on the surface of the silicon single-crystal substrate, the 3C-SiC single-crystal film having a thickness of 7 nm or less is formed on the surface of the silicon single-crystal substrate by an RTA-treatment in a carbon-containing gas atmosphere at 1150° C. to 1300° C.

15. The method for manufacturing a silicon single-crystal substrate according to claim 11, wherein in the step of oxidizing the 3C-SiC single-crystal film to be the oxide film and diffusing carbon inward the silicon single-crystal substrate, the RTA treatment is performed in the oxygen atmosphere at 1150° C. to 1400° C. for 1 to 60 seconds.

16. The method for manufacturing a silicon single-crystal substrate according to claim 12, wherein in the step of oxidizing the 3C-SiC single-crystal film to be the oxide film and diffusing carbon inward the silicon single-crystal substrate, the RTA treatment is performed in the oxygen atmosphere at 1150° C. to 1400° C. for 1 to 60 seconds.

17. The method for manufacturing a silicon single-crystal substrate according to claim 13, wherein in the step of oxidizing the 3C-SiC single-crystal film to be the oxide film and diffusing carbon inward the silicon single-crystal substrate, the RTA treatment is performed in the oxygen atmosphere at 1150° C. to 1400° C. for 1 to 60 seconds.

18. The method for manufacturing a silicon single-crystal substrate according to claim 14, wherein in the step of oxidizing the 3C-SiC single-crystal film to be the oxide film and diffusing carbon inward the silicon single-crystal substrate, the RTA treatment is performed in the oxygen atmosphere at 1150° C. to 1400° C. for 1 to 60 seconds.

19. The method for manufacturing a silicon single-crystal substrate according to claim 11, wherein in the step of removing the oxide film, the oxide film is etched by an RTA treatment in a hydrogen atmosphere at 1150° C. to 1400° C. for 1 to 60 seconds.

20. The method for manufacturing a silicon single-crystal substrate according to claim 11, wherein in the step of removing the oxide film, etching is performed with 0.1 to 5.0% hydrofluoric acid, an aqueous HF solution, for shorter than 10 minutes, and then rinsing is performed with pure water.

21. The method for manufacturing a silicon single-crystal substrate according to claim 11, wherein the step of oxidizing the 3C-SiC single-crystal film to be the oxide film and diffusing carbon inward the silicon single-crystal substrate and the step of removing the oxide film are repeated.

22. A method for manufacturing a silicon epitaxial wafer, the method comprising forming an epitaxial layer on a silicon single-crystal substrate manufactured by the method for manufacturing a silicon single-crystal substrate according to claim 11.

23. A silicon single-crystal substrate, comprising a carbon diffusion layer on a surface, wherein
the carbon diffusion layer has a carbon concentration of 1×10¹⁷ atoms/cm³ or more and a thickness of 2 μm or more.

24. A silicon epitaxial wafer, comprising an epitaxial layer on the carbon diffusion layer in the silicon single-crystal substrate according to claim 23.
